(19) United States
(12) Patent Application Publication
(10) Pub. No.: US 2007/0291571 A1
(43) Pub. Date: Dec. 20, 2007

(54) Increasing the battery life of a mobile computing system in a reduced power state through memory compression

(75) Inventor: Sai P. Balasundaram, Beaverton, OR (US)

Correspondence Address: INTEL CORPORATION;c/o INTELLEVATE, LLC, P.O. BOX 52050, MINNEAPOLIS, MN, 55402, US

(73) Assignee: INTEL CORPORATION

(21) Appl. No.: 11/450,214

(22) Filed: Jun. 8, 2006

(51) Int. Cl. G06F 12/00; G11C 14/00; G06F 13/28; G11C 5/14; G11C 11/34; G06F 13/00

(52) U.S. Cl. 365/227; 365/185.08; 711/165

(57) ABSTRACT

Embodiments of the invention are generally directed to systems, methods, and apparatuses for increasing the battery life of a mobile computing system through memory compression. In some embodiments, an integrated circuit includes compression logic to compress at least a portion of the data in volatile memory independent of an operating system. The compression logic may compress the data responsive to an indication to transition to a reduced power state.

### TECHNICAL FIELD

Embodiments of the invention generally relate to the field of integrated circuits and, more particularly, to systems, methods, and apparatuses for increasing the battery life of a mobile computing system in a reduced power state through memory compression.

### BACKGROUND

Mobile computing systems use batteries to provide a power source. While the demands on battery power have increased over time, battery performance has not kept pace with the demands. One of the ways to increase battery life is to reduce the power consumed by the components of the computing system.

Memory devices (such as dynamic random access memory (DRAM) devices) account for a significant fraction of the power consumed by a computing system, particularly when the computing system is in a reduced power state. For example, depending on the characteristics of the reduced power state and the amount of installed memory, the power consumed by the DRAM devices can account for nearly 50% of the total system power. A projected increase in minimum recommended memory for laptops, coupled with future DRAM devices having higher densities will increase the power consumption of system memory.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a block diagram illustrating selected aspects of a computing system implemented according to an embodiment of the invention.

FIG. 2 is a block diagram illustrating selected aspects of a computing system implemented according to an alternative embodiment of the invention.

FIG. 3 is a block diagram illustrating selected aspects of compression logic implemented according to an embodiment of the invention.

FIGS. 4A and 4B illustrate, respectively, selected aspects of a memory array before and after the data within the memory array is compressed, according to an embodiment of the invention.

FIG. 5 is a flow diagram illustrating selected aspects of a method for increasing the battery life of a mobile system through memory compression, according to an embodiment of the invention.

FIG. 6 is a block diagram illustrating selected aspects of an electronic system according to an embodiment of the invention.

FIG. 7 is a bock diagram illustrating selected aspects of an electronic system according to an alternative embodiment of the invention.

### DETAILED DESCRIPTION

Embodiments of the invention are generally directed to systems, methods, and apparatuses for increasing the battery life of a mobile computing system through memory compression. In some embodiments, the contents of a system's main memory are compressed prior to going into a reduced power to state. In such embodiments, only the portions of main memory that contain the compressed data need to be refreshed. The remaining portions of memory can be powered off which reduces the amount of power consumed and, thereby, extends the battery life.

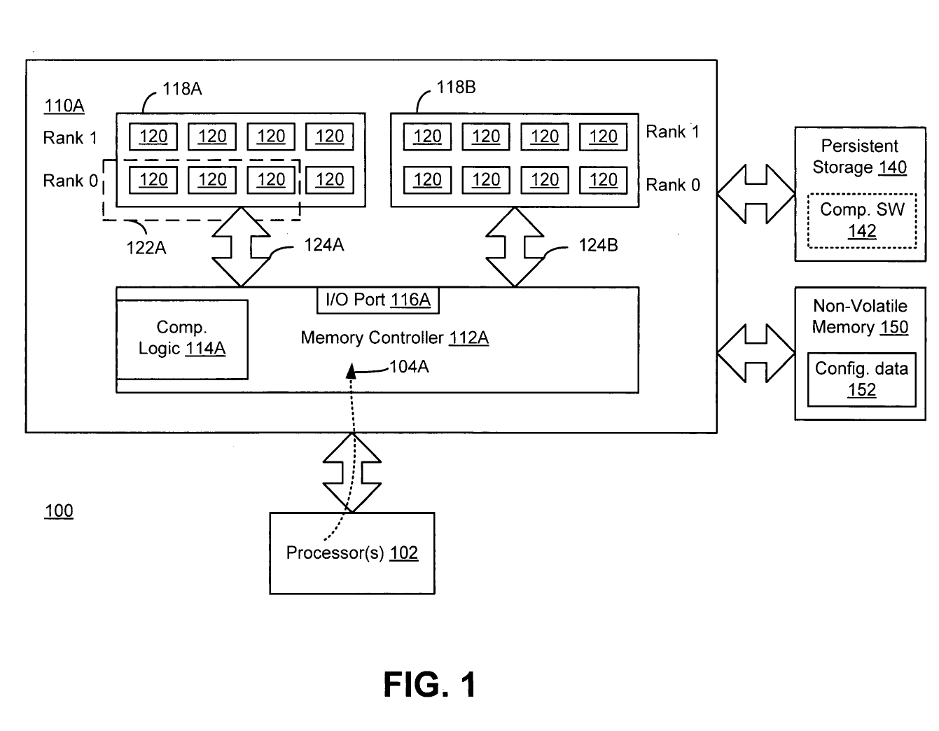

FIG. 1 is a block diagram illustrating selected aspects of a mobile computing system implemented according to an embodiment of the invention. The term “mobile computing system” broadly refers to, for example, laptops, palmtops, tablets, handhelds, cellular phones, personal digital assistants, and the like. System 100 includes processor(s) 102, memory subsystem 110, persistent storage 140, and non-volatile memory 150. In alternative embodiments, system 100 may include more elements, fewer elements, and/or different elements.

Processor 102 may be any type of processing device. For example, processor 102 may be a microprocessor, a microcontroller, or the like. Further, processor 102 may include any number of processing cores or may include any number of separate processors.

Memory subsystem 110 includes memory controller 112 and memory modules 118. Memory controller 112 provides an interface between processor(s) 102 and the other elements shown in FIG. 1. Memory controller 112 includes compression logic 114 and input/output port 116. Input/output (I/O) port 116 may include a receiver, a transmitter, and associated circuitry to exchange information with other integrated circuits.

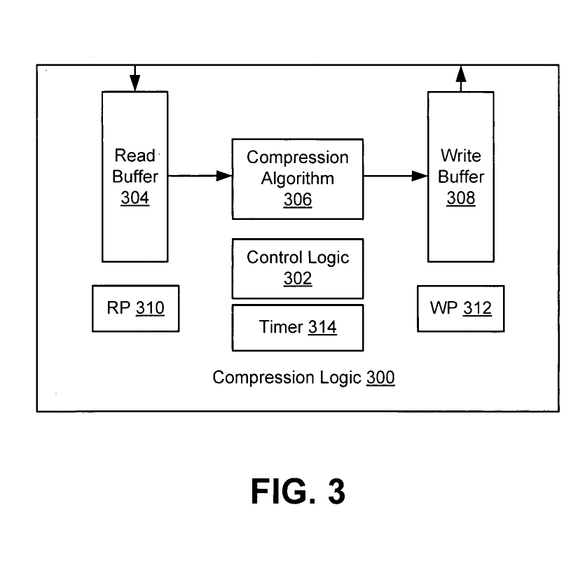

In some embodiment, compression logic 114 includes logic to compress the data stored in memory modules 118 (e.g., a compression algorithm). Compression logic 114 may also include logic to selectively transition those memory devices 120 that contain compressed data (e.g., 122) to a self-refresh state. The remaining memory devices (e.g., other than 122) may be powered off. Since there is a reduction in the number of memory devices that are in the self-refresh state, there is a corresponding reduction in the amount of power consumed by the system. The term “self-refresh state” broadly refers to a state in which the cells of the memory device are periodically refreshed. Selected aspects of compression logic 114 are further discussed below with reference to FIG. 3.

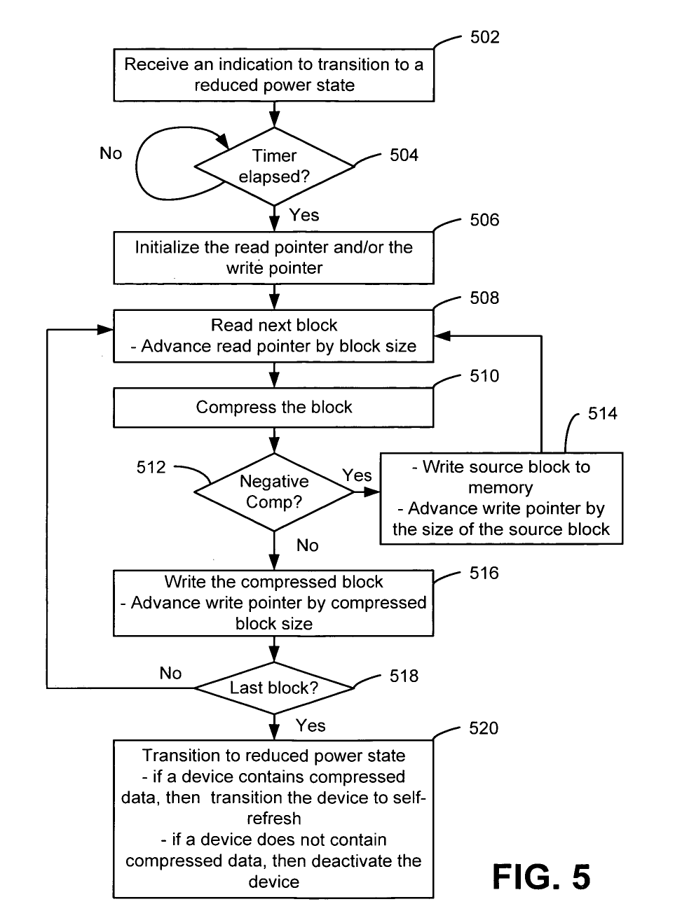

In some embodiments, compression logic 114 compresses the data in response to an indication to transition to a reduced power state. A user, for example, (or another computing system) may initiate a globally reduced power state (e.g., by closing the lid of a laptop computer). In response to the input, processor 102 sends a command 104 to the memory controller instructing it to transition to a reduced power state. The term “reduced power state” broadly refers to any power state in which the computing system uses less power than it does in its fully active power state. Examples of reduced power states include suspend, standby, soft-off, and the like. In some embodiments, the reduced power state is the suspend to random access memory (RAM) state (sometimes called the S3 state). Compressing the data in memory is further discussed below with reference to FIG. 5.

Persistent storage 140 provides persistent storage of data and code for system 100. Persistent storage 140 may include a magnetic disk or an optical disc and its corresponding drive. As indicated by the dashed line, in some alternative embodiments, persistent storage 140 includes compression software 142. Compression software 142 may augment and/or supplant aspects compression logic 114. For example, in some embodiments, compression software 142 may provide a compression algorithm for compression logic 114.

Non-volatile memory 150 provides non-volatile storage for code and/or data that may be used during, for example, system start-up and/or initiation. Non-volatile memory 150 may include a flash memory device and its interface. In some embodiments, non-volatile memory 150 includes configuration data 152. Configuration data 152 provides information about the configuration of memory modules 118 and/or memory devices 120. For example, configuration data 152 may specify the memory module types (e.g., x4, x8, x16), the size of the memory devices, and the like. As is further discussed below, compression logic 114 may access configuration data 152 to determine the configuration of one or more aspects of memory subsystem 110.

Memory modules 118 may have any of a wide variety of structures and pin configurations. For example, memory modules 118 may be structured as dual inline memory modules (DIMMs), small outline DIMMs (SO-DIMMs), micro DIMMs, and the like. Memory modules 118 may be coupled to interconnect 124 with an electrical contact connector having nearly any pin configuration including 240-pin, 144-pin, 72-pin, etc.

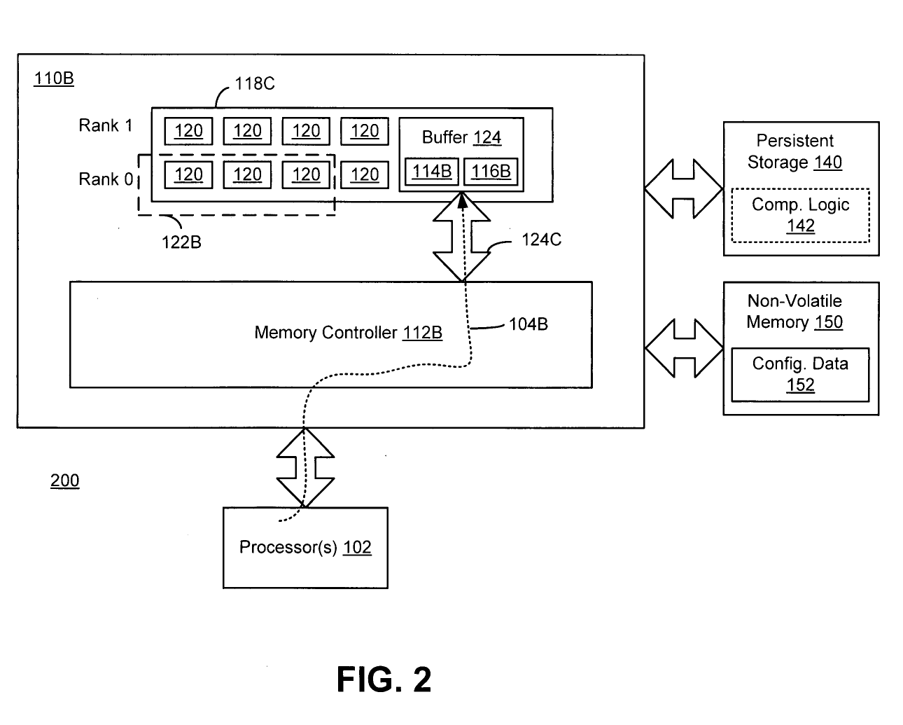

In alternative embodiments, compression logic 114 is located on an integrated circuit other than the memory controller. For example, compression logic 114 may be located on a separate microcontroller within the chipset. Alternatively, compression logic 114 may be located on memory module 118. FIG. 2 is a block diagram illustrating selected aspects of computing system 200 in which compression logic 114B is resident on memory module 118C.

In some embodiments, memory module 118C includes buffer 124. Buffer 124 may separate a relatively high-speed serial interconnect 124C from the comparatively slower interconnect used to interface with memory devices 120. In some embodiments, buffer 124 is an advanced memory buffer (AMB) suitable for use with fully-buffered dual inline memory module (FB-DIMM) technology.

Buffer 124 includes compression logic 114B and I/O port 116B. In some embodiments, compression logic 114B includes logic to compress the data stored in memory devices 120 independent of an operating system. That is, compression logic 114 may be capable of compressing the data independently of the operating system's memory manager. In some embodiments, compression logic 114 compresses the data responsive (at least in part) to an indication to transition to a reduced power state. In the illustrated embodiment, for example, compression logic 114 compresses the data in response to a command 104B (e.g., a suspend to RAM command) from processor 102.

FIG. 3 is a block diagram illustrating selected aspects of compression logic implemented according to an embodiment of the invention. Compression logic 300 includes control logic 302, read buffer 304, compression algorithm 306, write buffer 308, read pointer 310, write pointer 312, and timer 314. In alternative embodiments, compression logic 300 may include more elements, fewer elements, and/or different elements. In some embodiments, compression logic 300 is implemented in hardware and/or firmware within a computing system's platform (e.g., on the memory controller). In alternative embodiments, selected aspects of compression logic 300 may performed by software stored in persistent storage (e.g., persistent storage 140, shown in FIG. 1). In yet other alternative embodiments, compression logic 300 may be resident on a memory module.

In some embodiments, control logic 302 provides the overall control for compression logic 300. For example, compression logic 302 may detect an indication to transition to a low power state (e.g., command 104 shown in FIGS. 1 and 2). It may also control the process of reading data from memory into read buffer 304, compressing it, and writing the compressed data back to memory from write buffer 308. Read buffer 304 and write buffer 308 may be any storage element capable of storing a relatively small amount of data. Compression algorithm 306 may be any of a wide range of compression algorithms including, for example, the PKZIP compression algorithm.

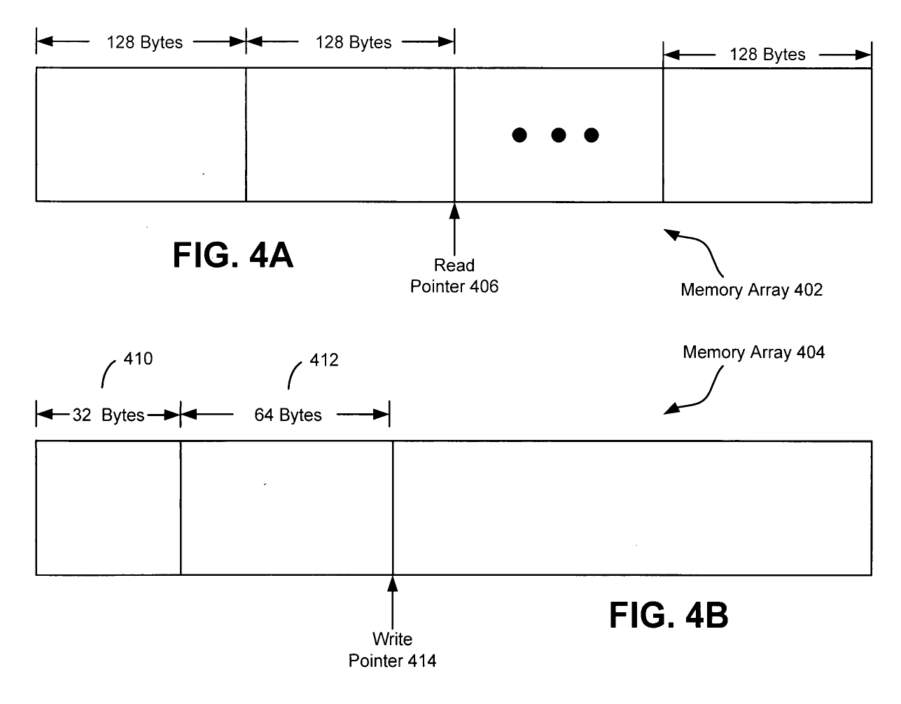

In some embodiments, control logic 302 uses read pointer 310 to indicate the location of the next block of data to be read from memory. Similarly, control logic 302 may use write pointer 312 to indicate where in memory the next block of compressed data will be written. Read pointer 310 and write pointer 312 are further discussed below with reference to FIGS. 4A and 4B.

In some embodiments, compression logic 300 does not immediately compress the data stored in memory when it receives an indication that the system is transition to a reduced power state. Instead, it waits a specified period of time before it initiates the compression process. The delay in initiating the compression process mitigates against the case in which a transition to a reduced power state is closely followed in time by a transition to an active power state (e.g., closing and then almost immediately opening the lid of a laptop computer). In such cases, there is a risk of using more battery power to compress the data than is saved by powering down some memory devices for a short period of time. This risk is reduced by waiting a specified length of time (e.g., several seconds) before initiating the compression process because battery power is not used to compress the data until enough time has passed to indicate that the device is likely to be in a reduced power state for a non-trivial length of time (e.g., tens of seconds, minutes, hours, etc.).

In some embodiments, compression logic 300 uses timer 314 to determine whether the specified length of time has elapsed. Timer 314 may be any of a wide variety of timers capable of being implemented in an integrated circuit. In an alternative embodiment, compression logic 300 may use a different mechanism to determine whether the specified time has elapsed. In yet other alternative embodiments, compression logic 300 initiates the compression process without waiting for a specified length of time.

In some embodiments, compression logic 300 compresses data on a block-by-block basis. That is, compression logic 300 reads a block of data having a certain block size, compresses it, writes the compressed block back to memory, and then repeats the process for the next block of data until all of the data stored in memory has been compressed. In some embodiments, the block size is 128 bytes. In alternative embodiments, the block size may be, for example, 64 bytes, 256 bytes or any other size suitable for supporting a desired compression ratio.

In some embodiments, there are multiple channels from the memory controller to the DIMM's and compression can be done concurrently on both channels (e.g., to increase the speed of compression). Consider, for example, an embodiment in which a laptop computer has two channels. In such an embodiment, the system may have dedicated read/write buffers (e.g., 304, 308) for each channel. The system may also have a dedicated compression/decompression controller (e.g., 302) for each channel. Alternatively, the system may have one shared controller for both channels. The compression logic may be overlapped with the input/output (I/O) operations. For example, while compressed data is being written out to channel 2, the controller may compress data for channel 1.

FIGS. 4A and 4B are conceptual diagrams illustrating one example of compressing data on a block-by-block basis, according to an embodiment of the invention. In some embodiments, the compression logic reads a block of data (e.g., having a specified block size), compresses the data to create a compressed block of data, writes the compressed block of data into memory, and then repeats the process until all of the data in memory is compressed. Memory array 402 represents the memory locations provided by a memory subsystem in a single array (e.g., from a memory location having a lowest address to a memory location having a highest address). In some embodiments, the compression logic (e.g., compression logic 300, shown in FIG. 3) reads the data stored in memory array 402 in blocks having a specified block size. In the illustrated embodiment, the block size is 128 bytes. In some embodiments, read pointer 406 indicates the next block of data to be read from memory.

FIG. 4B illustrates an example of a memory array into which compressed blocks of data have been written, according to an embodiment of the invention. Memory array 404 includes compressed blocks 410 and 412. As illustrated in FIG. 4B, each compressed block may have a different block size because the compression algorithm may compress some data to a greater degree than other data. In some embodiments, write pointer 414 indicates where the next block of compressed data is to be written in memory (and/or where the last block of compressed data was written into memory).

FIG. 5 is a flow diagram illustrating selected aspects of a method for increasing the battery life of a mobile computing system through memory compression, according to an embodiment of the invention. Referring to process block 502, the compression logic receives an indication to transition to a reduced power state. The phrase “receiving an indication” broadly refers to, for example, directly or indirectly receiving a command, an instruction, a signal, or any other indication to transition to a reduced power state. For example, in some embodiments, the compression logic receives a command to transition to a suspend to RAM state.

Referring to process block 504, the compression logic waits for a timer to elapse. The purpose of the timer is to provide a delay so that the contents of memory are not compressed unless the system is likely to be in a reduced power state for a significant period of time (e.g., tens of seconds, minutes, hours, etc.). In some embodiments, the compression logic proceeds without waiting for a timer to elapse. Referring to process block 506, the compression logic initializes a read pointer and/or a writer pointer.

Referring to process block 508, the compression logic reads a block of data from memory. In some embodiments, the data is read from memory into a read buffer (e.g., read buffer 304, shown in FIG. 3). The read pointer may be advanced by the block size (e.g., by 64 bytes, 128 bytes, 256 bytes, etc.). The block of data is compressed at 510. In some embodiments, the data compression is performed by hardware (e.g., on the memory controller) and is independent of an operating system. In alternative embodiments, the compression algorithm may be provided by software stored in persistent storage.

Referring to process block 512, the compression logic determines whether negative compression has occurred. For example, the compression logic may determine whether the size of the compressed block is greater than the size of the uncompressed source block. If so, then the source block (e.g., the uncompressed block) is written back to memory (514). In addition, the write pointer is advanced by the size of the source block (514).

Referring to process block 516, if negative compression has not occurred, then the compressed block of data is written into memory from, for example, a write buffer (e.g., write buffer 308, shown in FIG. 3). In some embodiments, the write pointer is advanced by the compressed block size. The compression logic determines whether the last block of data has been compressed at 518. Determining whether the last block of data has been compressed may include determining whether the read pointer has traversed the memory array (e.g., using configuration 152, shown in FIG. 1).

If the last block of data has been compressed, then the compression logic transitions the memory subsystem to a reduced power state (520). For example, if a memory device contains compressed data, then the compression logic transitions the memory device to a self-refresh state. If the device does not contain compressed data, then the compression logic may deactivate the device. The amount of battery power consumed by the system is reduced because a number of memory devices are deactivated. In some embodiments, the compression logic uses, for example, a write pointer and the memory subsystem's configuration data to determine which memory devices contain compressed data and which memory devices do not contain compressed data.

Subsequent to compressing the data, the compression logic may implement a decompression phrase. The decompression phase may occur in response to an indication to transition to an increased power state. The indication to transition to an increased power state may include any signal, command, etc. to transition out of the reduced power state. For example, in some embodiments, the indication to transition to an increased power state may include opening the lid of a laptop computer. In some embodiments, the decompression is performed by working backwards from the end of the compressed block of data.

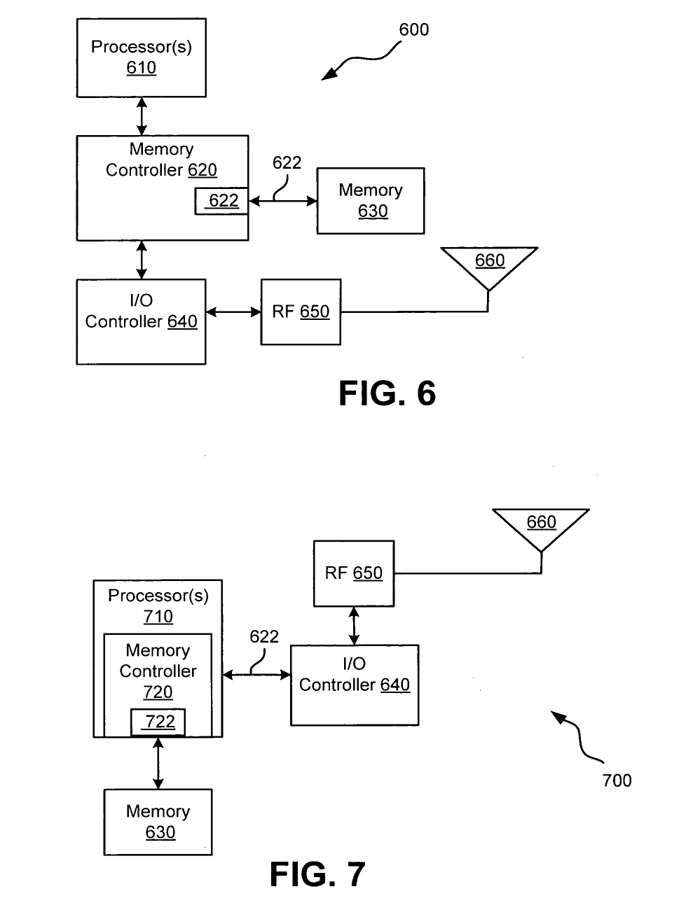

FIG. 6 is a block diagram illustrating selected aspects of an electronic system according to an embodiment of the invention. Electronic system 600 includes processor 610, memory controller 620, memory 630, input/output (I/O) controller 640, radio frequency (RF) circuits 650, and antenna 660. In operation, system 600 sends and receives signals using antenna 660, and these signals are processed by the various elements shown in FIG. 6. Antenna 660 may be a directional antenna or an omni-directional antenna. As used herein, the term omni-directional antenna refers to any antenna having a substantially uniform pattern in at least one plane. For example, in some embodiments, antenna 660 may be an omni-directional antenna such as a dipole antenna or a quarter wave antenna. Also, for example, in some embodiments, antenna 660 may be a directional antenna such as a parabolic dish antenna, a patch antenna, or a Yagi antenna. In some embodiments, antenna 660 may include multiple physical antennas.

Radio frequency circuit 650 communicates with antenna 660 and I/O controller 640. In some embodiments, RF circuit 650 includes a physical interface (PHY) corresponding to a communication protocol. For example, RF circuit 650 may include modulators, demodulators, mixers, frequency synthesizers, low noise amplifiers, power amplifiers, and the like. In some embodiments, RF circuit 650 may include a heterodyne receiver, and in other embodiments, RF circuit 650 may include a direct conversion receiver. For example, in embodiments with multiple antennas 660, each antenna may be coupled to a corresponding receiver. In operation, RF circuit 650 receives communications signals from antenna 660 and provides analog or digital signals to I/O controller 640. Further, I/O controller 640 may provide signals to RF circuit 650, which operates on the signals and then transmits them to antenna 660.

Processor(s) 610 may be any type of processing device. For example, processor 610 may be a microprocessor, a microcontroller, or the like. Further, processor 610 may include any number of processing cores or may include any number of separate processors.

Memory controller 620 provides a communication path between processor 610 and other elements shown in FIG. 6. In some embodiments, memory controller 620 is part of a hub device that provides other functions as well. As shown in FIG. 6, memory controller 620 is coupled to processor(s) 610, I/O controller 640, and memory 630. In some embodiments, memory controller 620 includes compression logic 622. Compression logic 622 may increase the battery life of system 600 through memory compression.

Memory 630 may include multiple memory devices. These memory devices may be based on any type of memory technology. For example, memory 630 may be random access memory (RAM), dynamic random access memory (DRAM), static random access memory (SRAM), nonvolatile memory such as FLASH memory, or any other type of memory.

Memory 630 may represent a single memory device or a number of memory devices on one or more modules. Memory controller 620 provides data through interconnect 622 to memory 630 and receives data from memory 630 in response to read requests. Commands and/or addresses may be provided to memory 630 through interconnect 622 or through a different interconnect (not shown). Memory controller 630 may receive data to be stored in memory 630 from processor 610 or from another source. Memory controller 620 may provide the data it receives from memory 630 to processor 610 or to another destination. Interconnect 622 may be a bi-directional interconnect or a unidirectional interconnect. Interconnect 622 may include a number of parallel conductors. The signals may be differential or single ended. In some embodiments, interconnect 622 operates using a forwarded, multiphase clock scheme.

Memory controller 620 is also coupled to I/O controller 640 and provides a communications path between processor(s) 610 and I/O controller 640. I/O controller 640 includes circuitry for communicating with I/O circuits such as serial ports, parallel ports, universal serial bus (USB) ports and the like. As shown in FIG. 6, I/O controller 640 provides a communication path to RF circuits 650.

FIG. 7 is a block diagram illustrating selected aspects of an electronic system according to an alternative embodiment of the invention. Electronic system 700 includes memory 630, I/O controller 640, RF circuits 650, and antenna 660, all of which are described above with reference to FIG. 6. Electronic system 700 also includes processor(s) 710 and memory controller 720. As shown in FIG. 7, memory controller 720 may be on the same die as processor(s) 710. In some embodiments, memory controller 720 includes compression logic 722. Compression logic 722 may increase the battery life of system 700 through memory compression. Processor(s) 710 may be any type of processor as described above with reference to processor 610. Example systems represented by FIGS. 6 and 7 include desktop computers, laptop computers, servers, cellular phones, personal digital assistants, digital home systems, and the like.

Elements of embodiments of the present invention may also be provided as a machine-readable medium for storing the machine-executable instructions. The machine-readable medium may include, but is not limited to, flash memory, optical disks, compact disks-read only memory (CD-ROM), digital versatile/video disks (DVD) ROM, random access memory (RAM), erasable programmable read-only memory (EPROM), electrically erasable programmable read-only memory (EEPROM), magnetic or optical cards, propagation media or other type of machine-readable media suitable for storing electronic instructions. For example, embodiments of the invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

Similarly, it should be appreciated that in the foregoing description of embodiments of the invention, various features are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed subject matter requires more features than are expressly recited in each claim. Rather, as the following claims reflect, inventive aspects lie in less than all features of a single foregoing disclosed embodiment. Thus, the claims following the detailed description are hereby expressly incorporated into this detailed description.

What is claimed is:

1. An integrated circuit comprising:
an input/output port to interface with volatile memory; and
compression logic coupled with the input/output port, the compression logic to compress at least a portion of the contents of volatile memory independent of an operating system.

2. The integrated circuit of claim 1, wherein the compression logic is to compress at least a portion of the contents in volatile memory responsive to an indication to transition to a reduced power state.

3. The integrated circuit of claim 2, wherein the indication to transition to the reduced power state comprises:
a command to transition to a suspend to random access memory (RAM) state.

4. The integrated circuit of claim 2, wherein the compression logic further comprises:
a timer to indicate when a threshold period of time has elapsed after receiving the indication to transition to the reduced power state.

5. The integrated circuit of claim 2, wherein the compression logic further comprises:
a first buffer to store a block of data read from volatile memory.

6. The integrated circuit of claim 5, wherein the compression logic further comprises:
a second buffer to store a compressed block of data to be written to volatile memory.

7. The integrated circuit of claim 2, wherein the compression logic includes logic to individually set a power state for each memory device in volatile memory.

8. The integrated circuit of claim 2, wherein the compression logic further comprises:
a read pointer to reference a block of uncompressed data; and
a write pointer to reference a block of compressed data.

9. The integrated circuit of claim 1, wherein the integrated circuit comprises a memory controller.

10. A method comprising:
receiving an indication to transition to a reduced power state; and
compressing at least a portion of data stored in a memory array responsive to receiving the indication to transition to the reduced power state.

11. The method of claim 10, wherein receiving the indication to transition to the reduced power state comprises:
receiving a suspend to random access memory (RAM) command.

12. The method of claim 10, wherein compressing at least a portion of the data stored in the memory array responsive to receiving the indication to transition to the reduced power state comprises:
compressing at least a portion of data stored in the memory array independent of an operating system.

13. The method of claim 12, further comprising:
determining whether a threshold period of time has elapsed.

14. The method of claim 13, wherein compressing at least a portion of the data stored in the memory array comprises:
compressing at least a portion of the data stored in the memory array if the threshold period of time has elapsed.

15. The method of claim 12, wherein compressing at least a portion of the data stored in the memory array independent of the operating system comprises:
reading a next block of data from volatile memory;
compressing the next block of data to create a compressed block of data; and
writing the compressed block of data to volatile memory.

16. The method of claim 10, further comprising:
transitioning to a reduced power state subsequent to compressing at least a portion of the data stored in the memory array.

17. The method of claim 10, further comprising:
receiving an indication to transition to an active power state; and
decompressing at least a portion of compressed data stored in the memory array responsive to receiving the indication to transition to the active power state.

18. A system comprising:
one or more memory devices to provide a memory array;
an integrated circuit coupled with the processor, the integrated circuit including compression logic to compress at least a portion of data stored in the memory array independent of an operating system;
a processor coupled with the integrated circuit; and
an antenna coupled with the processor.

19. The system of claim 18, wherein the compression logic is to compress at least a portion of the data stored in the memory array responsive at least in part to an indication from the processor to transition to a reduced power state.

20. The system of claim 19, wherein the indication to transition to the reduced power state comprises:
a command to transition to a suspend to random access memory (RAM) state.

21. The system of claim 19, wherein the compression logic further comprises:
a timer to indicate when a threshold period of time has elapsed after receiving the indication to transition to the reduced power state.

22. The system of claim 19, wherein the compression logic further comprises:
logic to individually set a power state for each memory device in the memory array.

23. The system of claim 18, wherein the integrated circuit comprises:
a memory controller.
